(19) United States
(12) Patent Application Publication
(10) Pub. No.: US 2024/0097040 A1
(43) Pub. Date: Mar. 21, 2024

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Tomoyuki FUNABASAMA, Yokkaichi Mie (JP)

(73) Assignee: Kioxia Corporation, Tokyo (JP)

(21) Appl. No.: 18/460,236

(22) Filed: Sep. 1, 2023

(30) Foreign Application Priority Data
Sep. 16, 2022 (JP) 2022-147548

(51) Int. Cl. H01L 29/786; H01L 29/66; H10B 41/35; H10B 43/35

(52) U.S. Cl. CPC H01L 29/78609; H01L 29/66742; H01L 29/7869; H10B 41/35; H10B 43/35

(57) ABSTRACT

A semiconductor device is provided with a substrate, a first transistor, and a second transistor. The first transistor has a first diffusion layer region, a second diffusion layer region, a first gate insulating film, a first gate electrode, and a first silicide layer. The first silicide layer is provided on the first diffusion layer region and the second diffusion layer region. The second transistor has a third diffusion layer region, a fourth diffusion layer region, a second gate insulating film, a second gate electrode, and a second silicide layer. The second silicide layer is provided on the third diffusion layer region and the fourth diffusion layer region. A distance between the first silicide layer and the first gate insulating film is larger than a distance between the second silicide layer and the second gate insulating film.

### CROSS-REFERENCE TO RELATED APPLICATIONS

This application is based upon and claims the benefit of priority from Japanese Patent Application No. 2022-147548, filed Sep. 16, 2022, the entire contents of which are incorporated herein by reference.

### FIELD

Embodiments described herein relate generally to a semiconductor device and a method of manufacturing a semiconductor device.

### BACKGROUND

A semiconductor device provided with a semiconductor substrate and a transistor provided on the semiconductor substrate is known.

### DESCRIPTION OF THE DRAWINGS

FIG. 1 is a cross-sectional view of a configuration example of a semiconductor device according to at least one embodiment.

FIG. 2 is a cross-sectional view of a configuration example of a semiconductor substrate and a first transistor according to the embodiment.

FIG. 3 is a cross-sectional view of a configuration example of the semiconductor substrate and a second transistor according to the embodiment.

FIG. 4 is a diagram illustrating a method of manufacturing the semiconductor device according to an embodiment.

FIG. 5 is a diagram illustrating a method of manufacturing the semiconductor device according to an embodiment.

FIG. 6 is a diagram illustrating a method of manufacturing the semiconductor device according to an embodiment.

FIG. 7 is a diagram illustrating a method of manufacturing the semiconductor device according to an embodiment.

FIG. 8 is a diagram illustrating a method of manufacturing the semiconductor device according to an embodiment.

FIG. 9 is a diagram illustrating a method of manufacturing the semiconductor device according to an embodiment.

### DETAILED DESCRIPTION

Embodiments provide a semiconductor device and a method of manufacturing a semiconductor device that can improve electrical characteristics.

In general, according to at least one embodiment, the semiconductor device is provided with a substrate, a first transistor, and a second transistor. The first transistor has a first diffusion layer region, a second diffusion layer region, a first gate insulating film, a first gate electrode, and a first silicide layer. The first diffusion layer region and the second diffusion layer region are provided on the substrate. The first gate insulating film is provided on the substrate, and at least a part of the first gate insulating film faces a region between the first diffusion layer region and the second diffusion layer region. The first gate electrode is located on a side opposite to the substrate with respect to the first gate insulating film. The first silicide layer is provided on the first diffusion layer region and the second diffusion layer region. The second transistor has a third diffusion layer region, a fourth diffusion layer region, a second gate insulating film, a second gate electrode, and a second silicide layer. The third diffusion layer region and the fourth diffusion layer region are provided on the substrate. The second gate insulating film is provided on the substrate, and at least a part of the second gate insulating film faces a region between the third diffusion layer region and the fourth diffusion layer region. The second gate electrode is located on a side opposite to the substrate with respect to the second gate insulating film. The second silicide layer is provided on the third diffusion layer region and the fourth diffusion layer region. The first silicide layer is provided apart from the first gate insulating film. A first distance between the first silicide layer and the first gate insulating film is larger than a second distance between the second silicide layer and the second gate insulating film.

The semiconductor device and the method of manufacturing a semiconductor device according to embodiments will be described below with reference to drawings. In the following description, configurations having the same or similar functions are designated by the same reference numerals. Then, the duplicate description of those configurations may be omitted. Terms “parallel,” “orthogonal,” or “the same” may include respectively “substantially parallel,” “substantially orthogonal,” or “substantially the same”. The term “connection” is not limited to mechanical connection and may include electrical connection. That is, the term “connection” is not limited to a case where a plurality of elements are directly connected, but may include a case where a plurality of elements are connected with another element interposed therebetween. The term “facing” means that two members overlap when viewed in a certain direction and may include a case where another member exists between the two members.

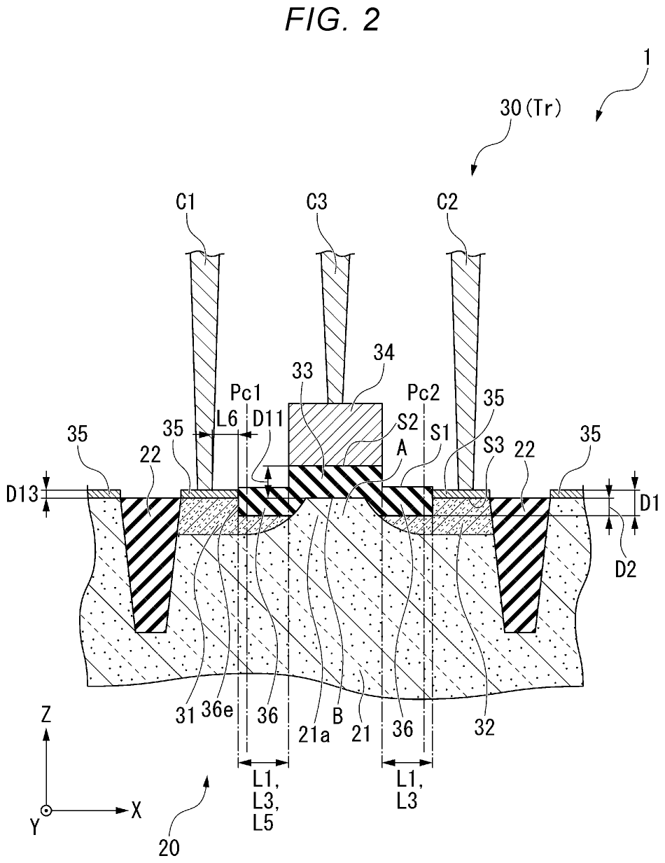

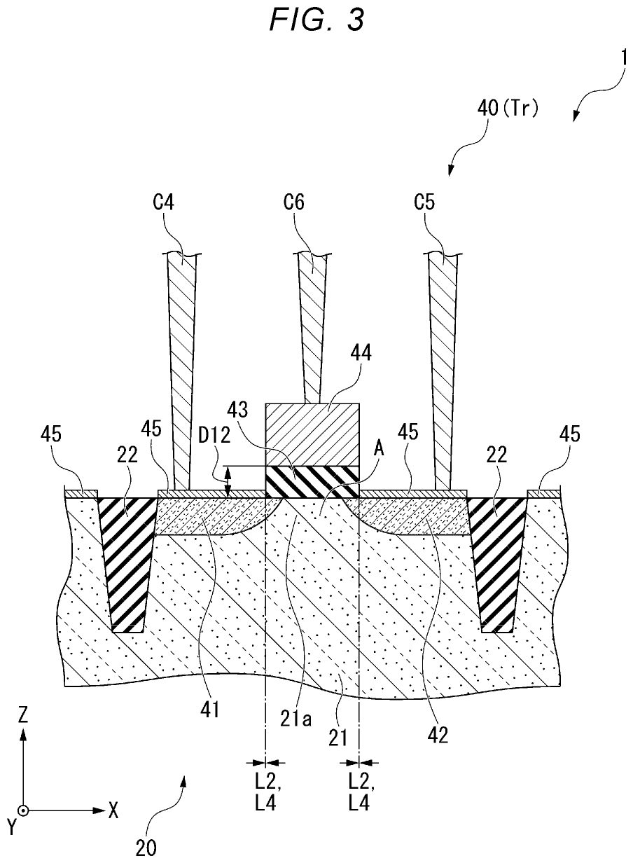

First, an X direction, a Y direction, and a Z direction are defined. The X direction and the Y direction are directions along a surface of a semiconductor substrate 20 described below (refer to FIGS. 2 and 3). The X direction is a direction from a source region 31 to a drain region 32 in a first transistor 30 described below (refer to FIG. 2), and a direction from a source region 41 toward a drain region 42 in a second transistor 40 described below (refer to FIG. 3). The Y direction is a direction that intersects (for example, is orthogonal to) the X direction. The Z direction is a direction that intersects (for example, is orthogonal to) the X direction and the Y direction. The Z direction is a thickness direction of the semiconductor substrate 20 (refer to FIGS. 2 and 3). In the following description, a side on which a transistor Tr is located with respect to the semiconductor substrate 20 may be referred to as “upper”, and an opposite side may be referred to as “lower”. Here, these expressions are for convenience only and do not define a direction of gravity. The Z direction is an example of a “first direction”. The X direction is an example of a “second direction”.

### Embodiment

### 1. Configuration Example of Semiconductor Device

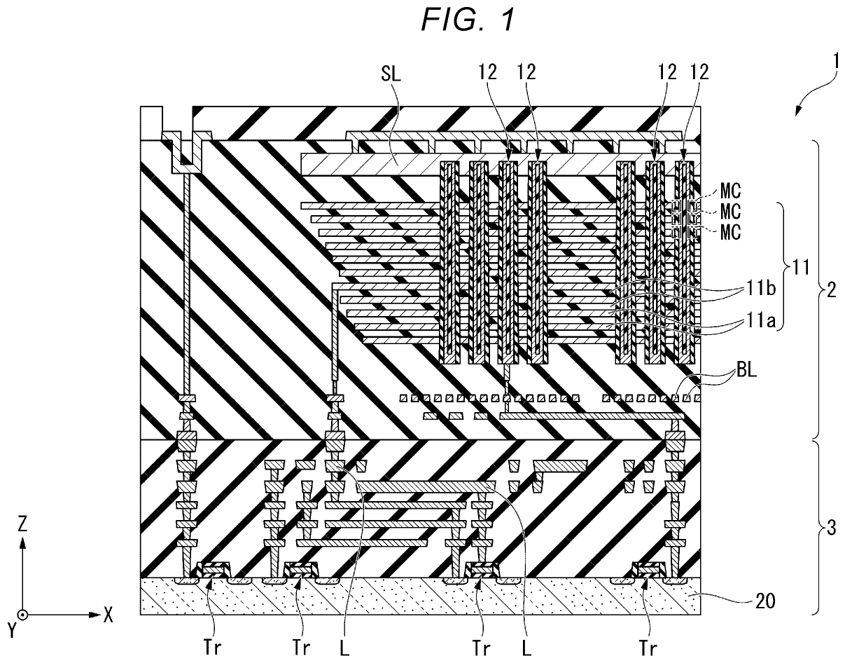

FIG. 1 is a cross-sectional view of a configuration example of a semiconductor device 1 according to an embodiment. The semiconductor device 1 is, for example, a semiconductor memory device such as a NAND flash memory. A semiconductor device 1 has, for example, an array chip 2 and a circuit chip 3.

The array chip 2 is a chip capable of storing information. The array chip 2 is provided with, for example, a stacked body 11, a plurality of memory pillars 12, a source line SL, and a plurality of bit lines BL. The stacked body 11 is provided with a plurality of word lines 11a and a plurality of insulating layers 11b. The plurality of word lines 11a and the plurality of insulating layers 11b are alternately stacked one by one in the Z direction.

The plurality of memory pillars 12 extend in the Z direction inside the stacked body 11. Each memory pillar 12 is provided with an insulating portion, a channel layer, a tunnel insulating film, an electric charge accumulation portion, and a block insulating film from a center portion of the memory pillar 12 toward an outer periphery side. One end portion of each memory pillar 12 is connected to the source line SL. The other end portion of each memory pillar 12 is connected to the bit line BL. A memory cell transistor MC is formed at an intersection portion of each memory pillar 12 and each word line 11a. The memory cell transistor MC is a storage element that can store information by accumulation of electric charges.

The circuit chip 3 is a control circuit that controls an operation of the array chip 2. The circuit chip 3 is provided with the semiconductor substrate 20, a plurality of transistors Tr, and a plurality of wirings L, for example. The plurality of transistors Tr are provided on the semiconductor substrate 20. The wiring L connects the transistor Tr and the array chip 2.

### 2. Configuration of Semiconductor Substrate and Transistor

Next, a configuration of the semiconductor substrate 20 and the transistor Tr will be described in detail.

2.1. Semiconductor Substrate

FIG. 2 is a cross-sectional view of a configuration example of the semiconductor substrate 20 and the first transistor 30 described below. FIG. 3 is a cross-sectional view of a configuration example of the semiconductor substrate 20 and the second transistor 40 described below.

The semiconductor substrate 20 is, for example, a silicon substrate. The semiconductor substrate 20 is an example of a “substrate”. As shown in FIGS. 2 and 3, the semiconductor substrate 20 has, for example, a substrate body 21 and an element isolation portion 22.

The substrate body 21 is a base portion on which the transistor Tr is provided. The substrate body 21 contains a silicon material. The substrate body 21 has, in at least a part of a region where the transistor Tr is provided, a well region 21a having a different polarity (different conductivity type) from a source region and a drain region of the transistor Tr described below.

The element isolation portion 22 is an isolation portion that electrically isolates the plurality of transistors Tr provided on the semiconductor substrate 20. The element isolation portion 22 is provided in the semiconductor substrate 20 to surround an active region A of each transistor Tr.

2.2. Transistor

The plurality of transistors Tr are provided with the first transistor 30 (refer to FIG. 2) and the second transistor 40 (refer to FIG. 3). Each of the first transistor 30 and the second transistor 40 is a field effect transistor, such as a metal-oxide-semiconductor-field-effect-transistor (MOSFET).

The first transistor 30 and the second transistor 40 are high voltage transistors to which a high voltage (for example, voltage of 20 V or more) is applied in the semiconductor device 1. The first transistor 30 and the second transistor 40 are transistors of the same size. In the present application, the term “transistors of the same size” means that a difference in thickness of gate insulating films (for example, gate insulating films 33 and 43) described below in the Z direction is 10% or less. Stated from another point of view, the term “transistors of the same size” may mean that a difference in thickness of gate electrodes (for example, gate electrodes 34 and 44) described below in the Z direction is 10% or less. In the first transistor 30 and the second transistor 40 of the same size, a part of the configuration of the transistor Tr (for example, gate electrodes 34 and 44) is collectively formed by, for example, a common process. In the present embodiment, the conductivity type of the first transistor 30 is different from the conductivity type of the second transistor 40.

2.2.1. First Transistor

The first transistor 30 is, for example, an n-type high voltage transistor. As shown in FIG. 2, the first transistor 30 has the source region 31, the drain region 32, the gate insulating film 33, the gate electrode 34, a first silicide layer 35, and a first insulating film 36.

The source region 31 and the drain region 32 are provided as a part of an upper portion of semiconductor substrate 20. The source region 31 and the drain region 32 are provided in the active region A corresponding to the first transistor 30. The source region 31 and the drain region 32 are separated from each other in the X direction. The source region 31 and the drain region 32 are formed by doping the upper portion of the semiconductor substrate 20 with an n-type impurity, for example, by ion implantation. In the present embodiment, each of the source region 31 and the drain region 32 is doped with P (phosphorus). The source region 31 is an example of a “first diffusion layer region”. The drain region 32 is an example of a “second diffusion layer region”.

A contact electrode C1 is provided above the source region 31. The contact electrode C1 is connected to the source region 31 in the Z direction. In the present embodiment, the contact electrode C1 extends in the Z direction, is in contact with the first silicide layer 35, and is connected to the source region 31 via the first silicide layer 35. The contact electrode C1 is an example of a “first contact electrode”. A contact electrode C2 is provided above the drain region 32. The contact electrode C2 is connected to the drain region 32 in the Z direction. In the present embodiment, the contact electrode C2 extends in the Z direction, is in contact with the first silicide layer 35, and is connected to the drain region 32 via the first silicide layer 35.

The gate insulating film 33 is located between the semiconductor substrate 20 and the gate electrode 34 and is an insulating film that electrically insulates the semiconductor substrate 20 and the gate electrode 34 from each other. The gate insulating film 33 is provided on the surface of the semiconductor substrate 20. At least a part of the gate insulating film 33 faces a region between the source region 31 and the drain region 32 in the Z direction. The gate insulating film 33 is made of silicon oxide, for example. The gate insulating film 33 is an example of a “first gate insulating film”. In the present application, the term “gate insulating film” refers to an insulating portion that is disposed between the gate electrode and the substrate and has a constant thickness in the Z direction (for example, portion having a thickness D11 in FIG. 2 and portion having a thickness D12 in FIG. 3).

The gate electrode 34 is located on a side opposite to the semiconductor substrate 20 with respect to the gate insulating film 33. At least a part of the gate electrode 34 faces the region between the source region 31 and the drain region 32 of the semiconductor substrate 20 with the gate insulating film 33 interposed therebetween in the Z direction. The gate electrode 34 is made of polysilicon containing an impurity, for example. The gate electrode 34 is an example of a “first gate electrode”. A contact electrode C3 is provided above the gate electrode 34. The contact electrode C3 is connected to the gate electrode 34 in the Z direction.

The first silicide layer 35 is provided on the source region 31 and the drain region 32. The first silicide layer 35 is separated from the gate insulating film 33 and the gate electrode 34.

The first insulating film 36 is provided between the first silicide layer 35 and the gate insulating film 33 on the source region 31 and the drain region 32. The first insulating film 36 functions as a block film that blocks formation of the first silicide layer 35. The first insulating film 36 is connected to and continuous with the gate insulating film 33. The gate insulating film 33 and the first insulating film 36 are oxide films.

On the source region 31, the first insulating film 36 extends from the gate insulating film 33 to a region closer to a contact electrode C1 side than an intermediate point Pc1 between the gate electrode 34 and the contact electrode C1. Further, on the drain region 32, the first insulating film 36 extends from the gate insulating film 33 to a region closer to a contact electrode C2 side than an intermediate point Pc2 between the gate electrode 34 and the contact electrode C2. The thickness D1 of the first insulating film 36 in the Z direction is, for example, 10 nm or more and 30 nm or less. The thickness D1 of the first insulating film 36 in the Z direction is smaller than the thickness D11 of the gate insulating film 33 in the Z direction. The thickness D1 of the first insulating film 36 in the Z direction is smaller than the thickness D12 of a gate insulating film 43 in the Z direction. The thickness D1 of the first insulating film 36 in the Z direction is larger than a thickness D13 of the silicide layer 35 in the Z direction.

A length of the first insulating film 36 in the X direction (corresponding to a distance L1 described below) is larger than the thickness D1 of the first insulating film in the Z direction. Further, the first insulating film 36 has a first end 36e in contact with the silicide layer 35. A distance L5 between the first end 36e and the gate insulating film 33 is longer than a distance L6 between the first end 36e and the contact electrode C1. The distance L5 is a distance corresponding to the distance L1 described below. The distance L6 is the distance between the first end 36e and the contact electrode C1 in the X direction (the direction from the source region 31 toward the drain region 32) and is, for example, the shortest distance between the first end 36e and the contact electrode C1 in the X direction.

At least a part of the first insulating film 36 is located on an inner side of the semiconductor substrate 20 (inner side in the Z direction) than the gate insulating film 33. For example, at least a part of the first insulating film 36 is located on the inner side of the semiconductor substrate 20 (inner side in the Z direction) than an interface B between the gate insulating film 33 and the semiconductor substrate 20.

More specifically, the first insulating film 36 is deeply formed on the inner side of the semiconductor substrate 20 than the interface B between the gate insulating film 33 and the semiconductor substrate 20 with, for example, a depth D2 of about 20 nm in the Z direction. Further, the first insulating film 36 has a surface S1 facing a side opposite to the semiconductor substrate 20. The gate insulating film 33 has a surface S2 facing the side opposite to the semiconductor substrate 20. The surface S1 of the first insulating film 36 is located on a semiconductor substrate 20 side in the Z direction from the surface S2 of the gate insulating film 33. The first silicide layer 35 has a surface S3 facing the semiconductor substrate 20 side. The surface S1 of the first insulating film 36 is located farther from the semiconductor substrate 20 in the Z direction than the surface S3 of the first silicide layer 35.

The first insulating film 36 is made of silicon oxide, like the gate insulating film 33. However, a component of the first insulating film 36 is different from a component of the gate insulating film 33. The first insulating film 36 contains an impurity having the same polarity as the impurity of the source region 31 and the drain region 32. In the present embodiment, the first insulating film 36 contains arsenic (As) as the impurity having the same polarity as the impurity of the source region 31 and the drain region 32.

In the first transistor 30 described above, a potential difference (maximum potential difference) applied between the source region 31 and the drain region 32 is set to 20 V or more, for example.

2.2.2. Second Transistor

The second transistor 40 is, for example, a p-type high voltage transistor. As shown in FIG. 3, the second transistor 40 has the source region 41, the drain region 42, the gate insulating film 43, a gate electrode 44, and a second silicide layer 45.

The source region 41 and the drain region 42 are provided as a part of the upper portion of semiconductor substrate 20. The source region 41 and the drain region 42 are provided in the active region A corresponding to the second transistor 40. The source region 41 and the drain region 42 are separated from each other in the X direction. The source region 41 and the drain region 42 are formed by doping the upper portion of the semiconductor substrate 20 with the impurity, for example, by ion implantation. In the present embodiment, each of the source region 41 and the drain region 42 is doped with boron (B). The source region 41 is an example of a “third diffusion layer region”. The drain region 42 is an example of a “fourth diffusion layer region”.

A contact electrode C4 is provided above the source region 41. The contact electrode C4 is connected to the source region 41 in the Z direction. In the present embodiment, the contact electrode C4 extends in the Z direction, is in contact with the second silicide layer 45, and is connected to the source region 41 via the second silicide layer 45. A contact electrode C5 is provided above the drain region 42. The contact electrode C5 is connected to the drain region 42 in the Z direction. In the present embodiment, the contact electrode C5 extends in the Z direction, is in contact with the second silicide layer 45, and is connected to the drain region 42 via the second silicide layer 45.

The gate insulating film 43 is located between the semiconductor substrate 20 and the gate electrode 44 and is an insulating film that electrically insulates the semiconductor substrate 20 and the gate electrode 44 from each other. The gate insulating film 43 is provided on the surface of the semiconductor substrate 20. At least a part of the gate insulating film 43 faces a region between the source region 41 and the drain region 42 in the Z direction. The gate insulating film 43 is made of silicon oxide, for example. The gate insulating film 43 is an example of a “second gate insulating film”.

The gate electrode 44 is located on the side opposite to the semiconductor substrate 20 with respect to the gate insulating film 43. At least a part of the gate electrode 44 faces the region between the source region 41 and the drain region 42 of the semiconductor substrate 20 with the gate insulating film 43 interposed therebetween in the Z direction. The gate electrode 44 is made of polysilicon containing the impurity, for example. The gate electrode 44 is an example of a “second gate electrode”. A contact electrode C6 is provided above the gate electrode 44. The contact electrode C6 is connected to the gate electrode 44 in the Z direction.

The second silicide layer 45 is provided on the source region 41 and the drain region 42. The second silicide layer 45 is provided, for example, over the entire surface of the source region 41 and the drain region 42 (for example, in a case where a part of each of the source region 41 and the drain region 42 is located below the gate insulating film 43, the entire surface except for the part). The second silicide layer 45 is in contact with the gate insulating film 43.

In the second transistor 40 described above, a potential difference (for example, maximum potential difference) applied between the source region 41 and the drain region 42 is set to 20 V or more, for example.

2.2.3. Differences Between First and Second Transistors

Next, differences between the first transistor 30 and the second transistor 40 will be described with reference to both FIGS. 2 and 3.

As described above, the first transistor 30 has the first insulating film 36. For this reason, the gate insulating film 33 is separated from the first silicide layer 35 in the first transistor 30, unlike the gate insulating film 43 and the second silicide layer 45 in the second transistor 40. A first distance L1 between the first silicide layer 35 and the gate insulating film 33 is longer than a second distance L2 between the second silicide layer 45 and the gate insulating film 43. The first distance L1 is a distance between the first silicide layer 35 and the gate insulating film 33 in the X direction (direction from the source region 31 toward the drain region 32) and is, for example, the shortest distance between the first silicide layer 35 and the gate insulating film 33 in the X direction. The second distance L2 is a distance between the second silicide layer 45 and the gate insulating film 43 in the X direction (direction from the source region 41 toward the drain region 42) and is, for example, the shortest distance between the second silicide layer 45 and the gate insulating film 43 in the X direction. In the present embodiment, the second silicide layer 45 is in contact with the gate insulating film 43. In this case, the second distance L2 is zero. However, the second distance L2 is not limited to zero, and the second silicide layer 45 may be separated from the gate insulating film 43.

Stated from another point of view, a third distance L3 between the first silicide layer 35 and the gate electrode 34 is longer than a second distance L4 between the second silicide layer 45 and the gate electrode 44. The first distance L3 is a distance between the first silicide layer 35 and the gate electrode 34 in the X direction (direction from the source region 31 toward the drain region 32) and is, for example, the shortest distance between the first silicide layer 35 and the gate electrode 34 in the X direction. The fourth distance L4 is a distance between the second silicide layer 45 and the gate electrode 44 in the X direction (direction from the source region 41 toward the drain region 42) and is, for example, the shortest distance between the second silicide layer 45 and the gate electrode 44 in the X direction.

Both the first transistor 30 and the second transistor 40 are used, for example, as a word line driver or a select gate transistor for writing or erasing of the memory cell transistor MC, or for voltage application to the word line 11a. Here, the potential difference (for example, maximum potential difference) applied between the source region 31 and the drain region 32 in the first transistor 30 is larger than the potential difference (for example, maximum potential difference) applied between the source region 41 and the drain region 42 in the second transistor 40.

### 3. Method of Manufacturing Semiconductor Device

Next, a method of manufacturing the semiconductor device 1 will be described. Here, a manufacturing method of the first transistor 30 and the second transistor 40 will be described. A known method may be used for a process of manufacturing another configuration of the semiconductor device 1.

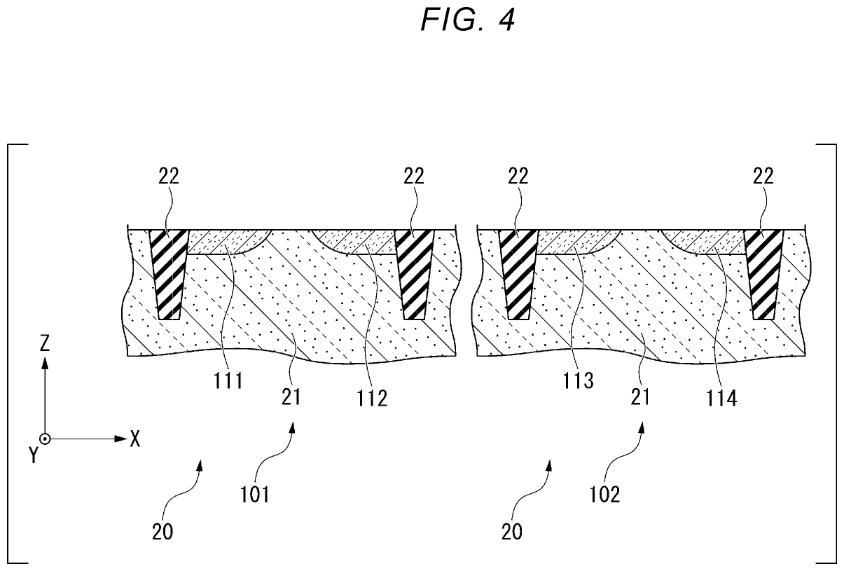

FIGS. 4 to 9 are diagrams illustrating the method of manufacturing the semiconductor device 1.

Hereinafter, a region in which the first transistor 30 is formed will be referred to as a first region 101, and a region in which the second transistor 40 is formed will be referred to as a second region 102.

First, as shown in FIG. 4, the element isolation portions 22 are provided in the semiconductor substrate 20 in both the first region 101 and the second region 102.

First, in the second region 102, a region between the two element isolation portions 22 on the semiconductor substrate 20 is doped with the impurity (boron (B) in the present embodiment). In this case, the ion implantation is performed in a state where a patterned resist is provided on the surface of the semiconductor substrate 20 to perform the impurity doping. The impurity is doped into a region closer to one element isolation portion 22 side of the two element isolation portions 22 and a region on the other element isolation portion 22 side, respectively. Accordingly, a third low-concentration diffusion layer region 113 and a fourth low-concentration diffusion layer region 114 separated from each other in the X direction are formed in the region between the two element isolation portions 22. The third low-concentration diffusion layer region 113 and the fourth low-concentration diffusion layer region 114 are so-called lightly doped drains (LDDs). A doping amount of the impurity in the third low-concentration diffusion layer region 113 and the fourth low-concentration diffusion layer region 114 is, for example, 10¹² to 10¹³ cm⁻².

The impurity doped to form the third low-concentration diffusion layer region 113 and the fourth low-concentration diffusion layer region 114 is not limited to boron (B).

Subsequently, in the first region 101, the region between the two element isolation portions 22 on the semiconductor substrate 20 is doped with a first impurity (phosphorus (P) in the present embodiment). In this case, for example, the ion implantation is performed by newly providing the patterned resist to perform the impurity doping. The first impurity is doped into a region closer to one element isolation portion 22 side of the two element isolation portions 22 and a region on the other element isolation portion 22 side, respectively. Accordingly, a first low-concentration diffusion layer region 111 and a second low-concentration diffusion layer region 112 separated from each other in the X direction are formed in the region between the two element isolation portions 22. The first low-concentration diffusion layer region 111 and the second low-concentration diffusion layer region 112 are so-called LDDs. A doping amount of the first impurity in the first low-concentration diffusion layer region 111 and the second low-concentration diffusion layer region 112 is, for example, 10¹² to 10¹³ cm⁻².

The first impurity doped to form the first low-concentration diffusion layer region 111 and the second low-concentration diffusion layer region 112 is not limited to phosphorus (P).

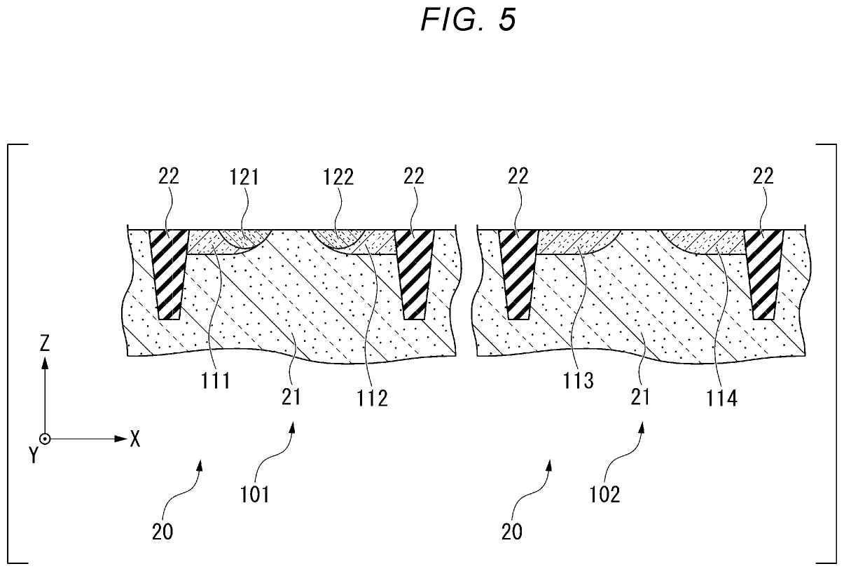

Next, as shown in FIG. 5, in the first region 101, the patterned resist is reapplied and the ion implantation is performed. Accordingly, a portion of the first low-concentration diffusion layer region 111 located on the second low-concentration diffusion layer region 112 side is doped with a second impurity (arsenic (As) in the present embodiment) having the same polarity as the first impurity in a higher concentration than the first impurity with which the first low-concentration diffusion layer region 111 is doped. Accordingly, a first high-concentration diffusion layer region 121 is formed in the portion of the first low-concentration diffusion layer region 111 located on the second low-concentration diffusion layer region 112 side.

At the same time, a portion of the second low-concentration diffusion layer region 112 located on the first low-concentration diffusion layer region 111 side is doped with the second impurity in a higher concentration than the first impurity with which the second low-concentration diffusion layer region 112 is doped. Accordingly, a second high-concentration diffusion layer region 122 is formed in the portion of the second low-concentration diffusion layer region 112 located on the first low-concentration diffusion layer region 111 side.

The first high-concentration diffusion layer region 121 and the second high-concentration diffusion layer region 122 are so-called highly doped drains (HDDs). A doping amount of the second impurity in the first high-concentration diffusion layer region 121 and the second high-concentration diffusion layer region 122 is, for example, 10¹⁴ to 10¹³ cm⁻². The doping amount of the second impurity in the first high-concentration diffusion layer region 121 and the second high-concentration diffusion layer region 122 is at least ×10 times or more than the doping amount of the first impurity in the first low-concentration diffusion layer region 111 and the second low-concentration diffusion layer region 112.

The second impurity doped to form the first high-concentration diffusion layer region 121 and the second high-concentration diffusion layer region 122 is not limited to arsenic (As). The second impurity may have the same polarity as the first impurity. In the present embodiment, the second impurity may be phosphorus (P), for example.

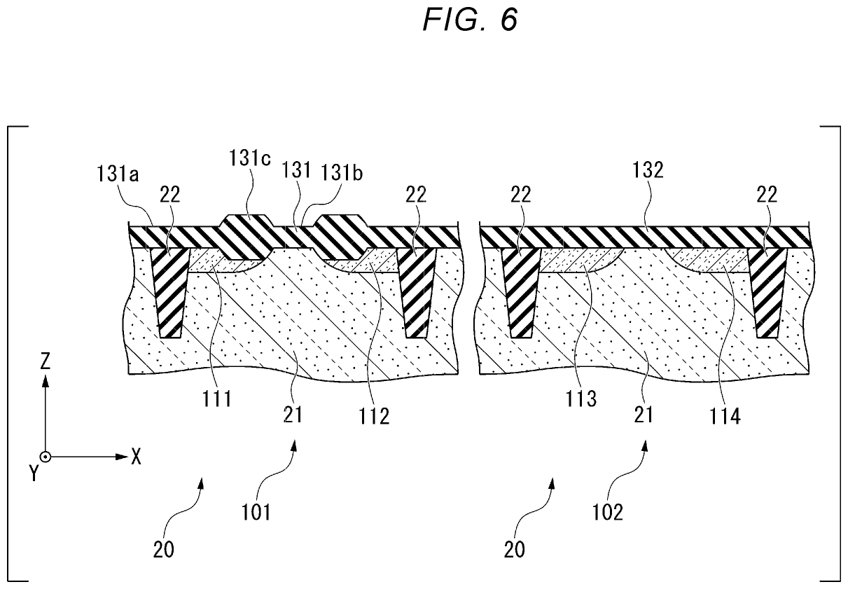

Next, as shown in FIG. 6, in the first region 101, the first high-concentration diffusion layer region 121 and the second high-concentration diffusion layer region 122 are formed, and then the surface of the semiconductor substrate 20 is heated and oxidized. Accordingly, a first oxide film 131 is formed. In this case, a portion (for example, a third portion 131c of the first oxide film 131) of the first oxide film 131, which is generated by the oxidation of the first high-concentration diffusion layer region 121 and the second high-concentration diffusion layer region 122, becomes thicker than other portions (for example, a first portion 131a of the first oxide film 131) on the semiconductor substrate 20 due to the presence of the doped second impurity. In the region (the first portion 131a of the first oxide film 131) other than the first high-concentration diffusion layer region 121 and the second high-concentration diffusion layer region 122, the first oxide film 131 has a uniform thickness.

In the second region 102, the surface of the semiconductor substrate 20 is also heated and oxidized. Accordingly, a second oxide film 132 having a uniform thickness is formed.

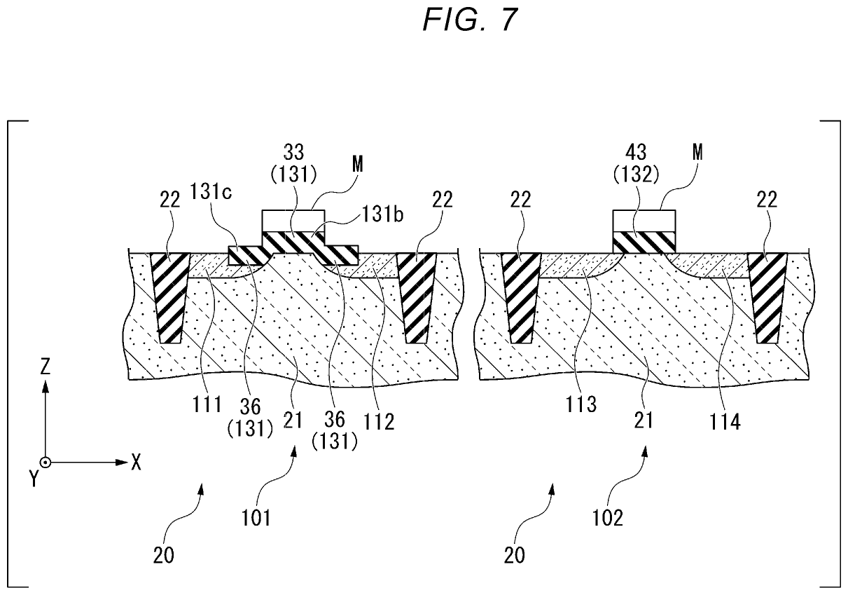

Next, as shown in FIG. 7, in the first region 101, an unnecessary portion of the first oxide film 131 (the first portion 131a of the first oxide film 131) is removed. The removal of unnecessary portion of the first oxide film 131 is performed, for example, by wet etching. In this case, a mask M is used to mask the first oxide film 131 (for example, a second portion 131b of the first oxide film 131) located between the first low-concentration diffusion layer region 111 and the second low-concentration diffusion layer region 112. This mask M is placed in a region between the first high-concentration diffusion layer region 121 and the second high-concentration diffusion layer region 122. A region of the first oxide film 131 located under the mask M is not removed. The first oxide film 131 (for example, the second portion 131b of the first oxide film 131) remaining under the mask M without being removed becomes the gate insulating film 33.

As described above, the region corresponding to the first high-concentration diffusion layer region 121 and the second high-concentration diffusion layer region 122, that is, the first oxide film 131 (for example, the third portion 131c of the first oxide film 131) in the region adjacent to the region under the mask M is thicker than other regions. For this reason, the first oxide film 131 (for example, the third portion 131c of the first oxide film 131) in the region adjacent to the region under the mask M is not entirely removed, but partially remains. The first oxide film 131 adjacent to the first oxide film 131 under the mask M forms the first insulating film 36.

When the etching is completed, non-oxidized portions of the first low-concentration diffusion layer region 111 and the second low-concentration diffusion layer region 112 are partially exposed.

Meanwhile, in the second region 102, an unnecessary portion of the second oxide film 132 is removed. The removal of unnecessary portion of the second oxide film 132 is performed, for example, by wet etching. In this case, the mask M is used to mask the second oxide film 132 between the third low-concentration diffusion layer region 113 and the fourth low-concentration diffusion layer region 114. The second oxide film 132 under the mask M is not removed. The second oxide film 132 remaining under the mask M without being removed becomes the gate insulating film 43.

When the etching is completed, non-oxidized portions of the third low-concentration diffusion layer region 113 and the fourth low-concentration diffusion layer region 114 are partially exposed.

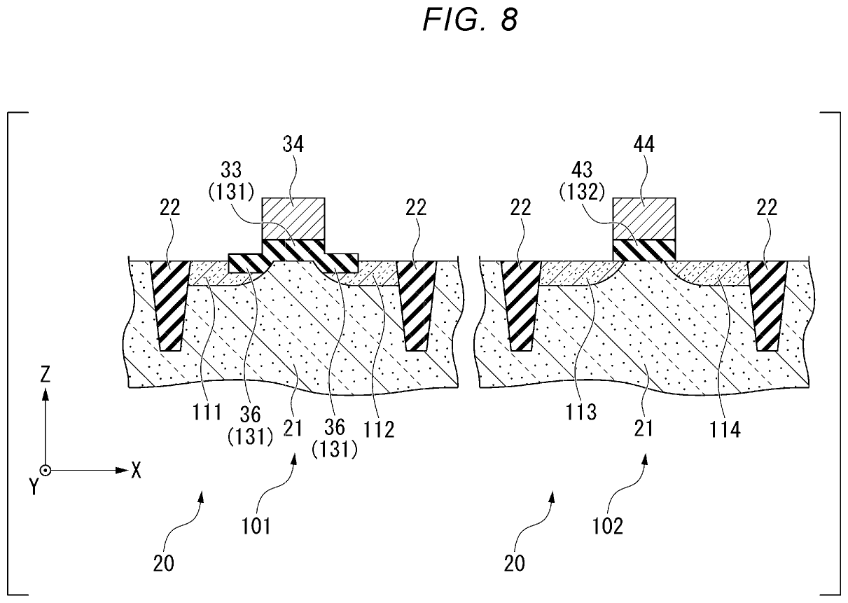

Next, as shown in FIG. 8, in the first region 101, the gate electrode 34 is formed on the first oxide film 131 (gate insulating film 33) remaining in the region under the mask M. In the second region 102 as well, the gate electrode 44 is formed on the second oxide film 132 (gate insulating film 43) remaining between the third low-concentration diffusion layer region 113 and the fourth low-concentration diffusion layer region 114.

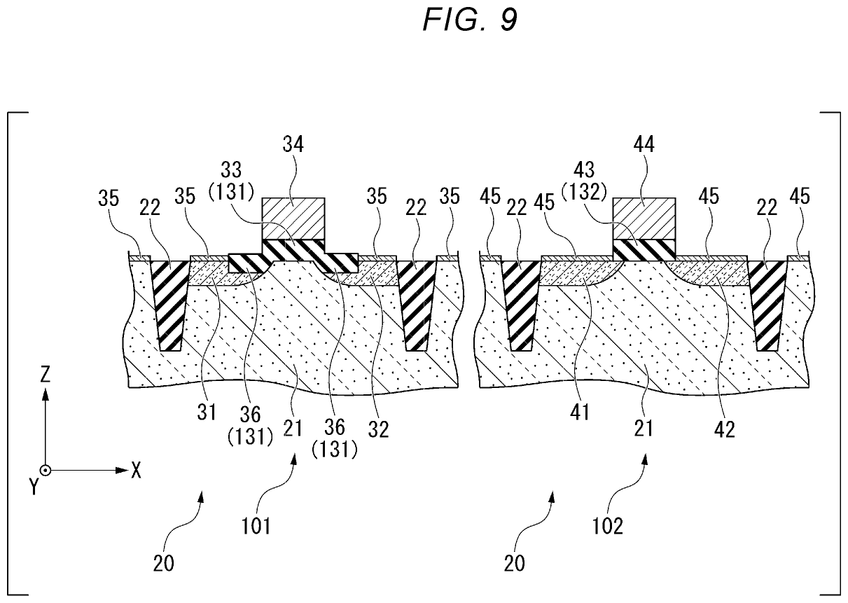

Next, as shown in FIG. 9, in the first region 101, the exposed first low-concentration diffusion layer region 111 and second low-concentration diffusion layer region 112 are further doped with the impurity of the same polarity by ion implantation, for example. Accordingly, the first low-concentration diffusion layer region 111 becomes the source region 31 and the second low-concentration diffusion layer region 112 becomes the drain region 32. Thereafter, a metal is dispersed on the semiconductor substrate 20 and is caused to react with the semiconductor substrate 20 to form the first silicide layer 35 on regions (surfaces of the source region 31 and the drain region 32) on the semiconductor substrate 20 exposed by removal of the first oxide film 131. The metal that is dispersed to form the first silicide layer 35 is not particularly limited, and examples thereof include Ni, Pt, Co, and Ti. The metal to form the first silicide layer 35 is desirably Ni with a small amount of Pt added.

In the second region 102, the exposed third low-concentration diffusion layer region 113 and fourth low-concentration diffusion layer region 114 are further doped with the impurity of the same polarity by ion implantation, for example. Accordingly, the third low-concentration diffusion layer region 113 becomes the source region 41 and the fourth low-concentration diffusion layer region 114 becomes the drain region 42. Thereafter, a metal is dispersed on the semiconductor substrate 20 and is caused to react with the semiconductor substrate 20 to form the second silicide layer 45 on regions (surfaces of the source region 41 and the drain region 42) on the semiconductor substrate 20 exposed by removal of the second oxide film 132. The metal that is dispersed to form the second silicide layer 45 is not particularly limited, and examples thereof include Ni, Pt, Co, and Ti. The metal to form the second silicide layer 45 is desirably Ni with a small amount of Pt added.

Next, in the first region 101, a contact electrode C 1 is formed on the first silicide layer 35 overlapping the source region 31 and a contact electrode C2 is formed on the first silicide layer 35 overlapping the drain region 32. Further, a contact electrode C3 is formed on the gate electrode 34. In this manner, the fabrication of the first transistor 30 shown in FIG. 2 is completed.

Similarly, in the second region 102, a contact electrode C4 is formed on the second silicide layer 45 overlapping the source region 41 and a contact electrode C5 is formed on the second silicide layer 45 overlapping the drain region 42. Further, a contact electrode C6 is formed on the gate electrode 44. In this manner, the fabrication of the second transistor 40 shown in FIG. 3 is completed.

### 4. Advantages

For example, in order to reduce a contact resistance of a transistor (resistance between a contact electrode and a source or drain region), a silicide layer may be formed over the entire surface of the source and drain regions. In such a transistor, a gate insulating film is in contact with the silicide layer. For this reason, when the transistor is driven, a depletion layer (not shown) under the gate insulating film extends toward the source region and the drain region, which makes it easier for the depletion layer and an impurity in the silicide layer to come into contact with each other. When the depletion layer comes into contact with the impurity in the silicide layer, a current leak path is generated between the depletion layer and the silicide layer. Accordingly, a breakdown voltage of the transistor deteriorates and a leak current is increased. As described above, there is still room for improvement from the viewpoint of improving electrical characteristics.

In the present embodiment, the first transistor 30 and the second transistor 40 are designed such that the first distance L1 between the first silicide layer 35 and the gate insulating film 33 in the first transistor 30 is larger than the second distance L2 between the second silicide layer 45 and the gate insulating film 43 in the second transistor 40.

Accordingly, in the first transistor 30, a distance between the first silicide layer 35 and the depletion layer generated during driving is increased. Even though the depletion layer under the gate insulating film 33 extends toward the source region 31 and the drain region 32 when the first transistor 30 is driven, contact between the depletion layer and the gate insulating film 33 is inhibited. Thus, the generation of the leak path between the depletion layer and the first silicide layer 35 is inhibited. Therefore, the deterioration in the breakdown voltage of the first transistor 30 and the generation of leak current are inhibited while the contact resistance is reduced by the first silicide layer 35, and the electrical characteristics are improved.

Meanwhile, in the second transistor 40, the second silicide layer 45 can be formed over the entire surface of the source region 41 and the drain region 42. Accordingly, in the second transistor 40, the second silicide layer 45 can further reduce the contact resistance and improve an ON current during driving.

In the present embodiment, the first transistor 30 has the first insulating film 36. The first insulating film 36 is provided between the first silicide layer 35 and the gate insulating film 33 on the source region 31 and the drain region 32 and is continuous with the gate insulating film 33. The gate insulating film 33 and the first insulating film 36 are oxide films.

Accordingly, the gate insulating film 33 and the first insulating film 36 can be collectively formed by the oxidation of the surface of the semiconductor substrate 20. Further, in the forming location of the first insulating film 36, the dispersed metal cannot be in contact with the surface of the semiconductor substrate 20 in the process of forming the first silicide layer 35 and thus a silicidation reaction does not occur. For this reason, the first silicide layer 35 and the gate insulating film 33 are reliably separated from each other. Thus, the generation of the leak path between the depletion layer under the gate insulating film 33 and the first silicide layer 35 is inhibited. That is, the deterioration in the breakdown voltage of the first transistor 30 and the generation of leak current are easily inhibited, and the electrical characteristics can be improved.

In the present embodiment, at least a part of the first insulating film 36 is located on the inner side of the semiconductor substrate 20 in the thickness direction (Z direction) of the semiconductor substrate 20 as compared with the gate insulating film 33. Accordingly, the distance between the first silicide layer 35 and the depletion layer further increases. The generation of leak path can be more reliably inhibited. Further, in the process of removing the unnecessary portion of the first oxide film 131, the first insulating film 36 easily remains on the semiconductor substrate 20.

In the present embodiment, the component of the first insulating film 36 is different from the component of the gate insulating film 33. The first insulating film 36 contains the second impurity having the same polarity as the first impurity of the source region 31. Accordingly, with the thickening of the first oxide film 131 of the portion to be the first insulating film 36 by the simple method of doping the second impurity and thermally oxidizing the surface of the semiconductor substrate 20 before the process of manufacturing the first insulating film 36, the first insulating film 36 can easily remain in the process of removing the unnecessary portion of the first oxide film 131.

In the present embodiment, the maximum potential difference applied between the source region 31 and the drain region 32 of the first transistor 30 is larger than the maximum potential difference applied between the source region 41 and the drain region 42 of the second transistor 40. Accordingly, the first distance L1 between the first silicide layer 35 and the gate insulating film 33 can be increased only for the first transistor 30 in which the potential difference is large and the depletion layer comes into contact with the first silicide layer 35, which is likely to cause the breakdown voltage deterioration or the leak current.

On the other hand, the potential difference between the source region 41 and the drain region 42 of the second transistor 40 is smaller than that of the first transistor 30. Thus, the leakage due to the contact between the depletion layer under the gate insulating film 43 and the second silicide layer 45 is less likely to be generated. For this reason, in the second transistor 40, the second silicide layer 45 can be formed over the entire surface of the source region 41 and the drain region 42. Therefore, the breakdown voltage deterioration and the leak current generation can be efficiently inhibited only for the first transistor 30.

In the present embodiment, the conductivity type of the first transistor 30 is different from the conductivity type of the second transistor 40. Accordingly, since the distance between the gate insulating film and the silicide layer can be increased only for the transistor of one conductivity type, the breakdown voltage deterioration and the leak current generation can be efficiently inhibited according to specifications.

In the present embodiment, the first transistor 30 is an n-type transistor and the second transistor 40 is a p-type transistor. Accordingly, since the distance between the gate insulating film and the silicide layer can be increased only for the n-type transistor, in which the potential difference between the source region and the drain region is large and the depletion layer tends to extend easily, the breakdown voltage deterioration and the leak current generation can be efficiently inhibited.

In the method of manufacturing the semiconductor device 1 of the present embodiment, first, the semiconductor substrate 20 is doped with the first impurity to form the first low-concentration diffusion layer region 111 and the second low-concentration diffusion layer region 112 separated from each other. Subsequently, the portion of the first low-concentration diffusion layer region 111 located on the second low-concentration diffusion layer region 112 side is doped with the second impurity having the same polarity as the first impurity in a higher concentration than the first impurity with which the first low-concentration diffusion layer region 111 is doped to form the first high-concentration diffusion layer region 121. Further, the portion of the second low-concentration diffusion layer region 112 located on the first low-concentration diffusion layer region 111 side is doped with the second impurity in a higher concentration than the first impurity with which the second low-concentration diffusion layer region 112 is doped to form the second high-concentration diffusion layer region 122. Subsequently, the first high-concentration diffusion layer region 121 and the second high-concentration diffusion layer region 122 are formed and then the surface of the semiconductor substrate 20 is oxidized to form the first oxide film 131. Then, the mask M is provided on the first oxide film 131 to remove the first portion 131a of the first oxide film 131, and the second portion 131b of the first oxide film 131 located in the region under the mask M and the third portion 131c of the first oxide film 131 located in the region adjacent to the region under the mask M are caused to remain. Next, the gate electrode 34 is formed on the second portion 131b of the first oxide film 131. Thereafter, a first silicide layer 35 is formed in the region on the semiconductor substrate 20 exposed by the removal of the first oxide film 131.

By the way, in a case where the surface of the semiconductor substrate is thermally oxidized to form the oxide film, in general, a rate of oxidation is higher when the impurity is present in the semiconductor substrate than when the impurity is not present in the semiconductor substrate. Therefore, the oxidation rate is higher as the concentration of the impurity to be doped is higher, and the oxide film is thicker.

In the present embodiment, the first low-concentration diffusion layer region 111 is further doped with the second impurity to form the first high-concentration diffusion layer region 121, and the second low-concentration diffusion layer region 112 is further doped with the second impurity to form the second high-concentration diffusion layer region 122. Since the surface of the semiconductor substrate 20 is oxidized to form the first oxide film 131 in this state, the first oxide film 131, which is generated by reaction between the first high-concentration diffusion layer region 121 and the second high-concentration diffusion layer region 122, becomes thicker. When the process of removing the unnecessary portion of the first oxide film 131 is performed in this state, the first oxide film 131, which is generated by reaction between the first high-concentration diffusion layer region 121 and the second high-concentration diffusion layer region 122, remains in a region other than the region under the mask M. The first oxide film 131 remaining in the region other than the region under the mask M becomes the first insulating film 36. In the process of forming the first silicide layer 35, the first insulating film 36 blocks the silicidation reaction only at the formation location of the first insulating film 36. Therefore, the first silicide layer 35 is formed at a position separated from the gate insulating film 33.

The second impurity doped into the first low-concentration diffusion layer region 111 and the second low-concentration diffusion layer region 112 is desirably an impurity that is difficult to be absorbed into the oxide film. This is because the impurity present at an interface between the semiconductor substrate and the oxide film is less likely to decrease as the oxide film is formed and the effect of increasing the thickness of the oxide film is easily maintained. Since arsenic (As) is particularly difficult to be absorbed into the oxide film, arsenic is more suitable for thickening the oxide film than another impurity such as phosphorus (P).

The embodiments have been described above. However, the embodiments are not limited to the examples described above.

Although the case where the semiconductor device 1 is provided with the first transistor 30 and the second transistor 40 has been described in the embodiments, the present disclosure is not limited thereto. The semiconductor device 1 may not be provided with the second transistor 40 as long as the semiconductor device is provided with the first transistor 30.

Although the first transistor 30 is an n-type transistor and the second transistor 40 is a p-type transistor in the embodiments, the present disclosure is not limited thereto. The first transistor 30 may be a p-type transistor and the second transistor 40 may be an n-type transistor.

Although the first diffusion layer region is the source region 31 and the second diffusion layer region is the drain region 32 in the embodiments, the present disclosure is not limited thereto. The first diffusion layer region may be the drain region and the second diffusion layer region may be the source region. Similarly, the case where the third diffusion layer region is the source region 41 and the fourth diffusion layer region is the drain region 42 has been described, but the present disclosure is not limited thereto. The third diffusion layer region may be the drain region and the fourth diffusion layer region may be the source region.

According to at least one embodiment described above, a semiconductor device is provided with a substrate, a first transistor, and a second transistor. The first transistor has a first diffusion layer region, a second diffusion layer region, a first gate insulating film, a first gate electrode, and a first silicide layer. The first silicide layer is provided on the first diffusion layer region and the second diffusion layer region. The second transistor has a third diffusion layer region, a fourth diffusion layer region, a second gate insulating film, a second gate electrode, and a second silicide layer. The second silicide layer is provided on the third diffusion layer region and the fourth diffusion layer region. The first silicide layer is provided apart from the first gate insulating film. A first distance between the first silicide layer and the first gate insulating film is larger than a second distance between the second silicide layer and the second gate insulating film. With such a configuration, the electrical characteristics can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a first transistor having:
a first diffusion layer region and a second diffusion layer region disposed on the substrate,
a first gate insulating film disposed on the substrate and at least partially facing a region between the first diffusion layer region and the second diffusion layer region,
a first gate electrode located on a side opposite to the substrate with respect to the first gate insulating film, and
a first silicide layer disposed on the first diffusion layer region and the second diffusion layer region; and
a second transistor having:
a third diffusion layer region and a fourth diffusion layer region disposed on the substrate,
a second gate insulating film disposed on the substrate and at least partially facing a region between the third diffusion layer region and the fourth diffusion layer region,
a second gate electrode located on a side opposite to the substrate with respect to the second gate insulating film, and
a second silicide layer disposed on the third diffusion layer region and the fourth diffusion layer region,
wherein the first silicide layer is disposed apart from the first gate insulating film, and
a distance between the first silicide layer and the first gate insulating film is larger than a distance between the second silicide layer and the second gate insulating film.

2. The semiconductor device according to claim 1,
wherein the first transistor and the second transistor have a same size.

3. The semiconductor device according to claim 1,
wherein a distance between the first silicide layer and the first gate electrode in a direction from the first diffusion layer region toward the second diffusion layer region is larger than a distance between the second silicide layer and the second gate electrode in a direction from the third diffusion layer region toward the fourth diffusion layer region.

4. The semiconductor device according to claim 1,
wherein the first transistor has a first insulating film disposed between the first silicide layer and the first gate insulating film on the first diffusion layer region and the second diffusion layer region and the first insulating film is continuous with the first gate insulating film, and
the first gate insulating film and the first insulating film are oxide films.

5. The semiconductor device according to claim 4,
wherein at least a part of the first insulating film is located on an inner side of the substrate in a thickness direction of the substrate as compared with the first gate insulating film.

6. The semiconductor device according to claim 4,
wherein a component of the first insulating film is different from a component of the first gate insulating film, and
the first insulating film contains an impurity having a same polarity as an impurity in the first diffusion layer region.

7. The semiconductor device according to claim 4,
wherein when a thickness direction of the substrate is a first direction, a thickness of the first insulating film in the first direction is smaller than a thickness of the first gate insulating film in the first direction.

8. The semiconductor device according to claim 7,
wherein the thickness of the first insulating film in the first direction is smaller than a thickness of the second gate insulating film in the first direction.

9. The semiconductor device according to claim 7,
wherein in a case where a direction from the first diffusion layer region toward the second diffusion layer region is a second direction,
a length of the first insulating film in the second direction is larger than the thickness of the first insulating film in the first direction.

10. The semiconductor device according to claim 4, further comprising:
a first contact electrode extending in a thickness direction of the substrate and being in contact with the first silicide layer,
wherein the first insulating film has a first end in contact with the first silicide layer, and
a distance between the first end and the first gate insulating film is larger than a distance between the first end and the first contact electrode.

11. The semiconductor device according to claim 1,
wherein a maximum potential difference applied between the first diffusion layer region and the second diffusion layer region of the first transistor is larger than a maximum potential difference applied between the third diffusion layer region and the fourth diffusion layer region of the second transistor.

12. The semiconductor device according to claim 1,
wherein a conductivity type of the first transistor is different from a conductivity type of the second transistor.

13. The semiconductor device according to claim 12,
wherein the first transistor is an n-type transistor, and
the second transistor is a p-type transistor.

14. A semiconductor device comprising:
a substrate; and
a transistor having:
a first diffusion layer region and a second diffusion layer region disposed on the substrate,
a gate insulating film disposed on the substrate and at least partially facing a region between the first diffusion layer region and the second diffusion layer region,
a gate electrode located on a side opposite to the substrate with respect to the first gate insulating film,
and a silicide layer disposed on the first diffusion layer region and the second diffusion layer region,
wherein the transistor has a first insulating film disposed between the silicide layer and the gate insulating film on the first diffusion layer region and the second diffusion layer region and is continuous with the gate insulating film,
a component of the first insulating film is different from a component of the gate insulating film, and
the first insulating film contains an impurity having a same polarity as an impurity in the first diffusion layer region.

15. A method of manufacturing a semiconductor device, comprising:
forming a first low-concentration diffusion layer region and a second low-concentration diffusion layer region separated from each other with doping of a first impurity on a substrate;
forming a first high-concentration diffusion layer region with doping, on a portion of the first low-concentration diffusion layer region located on a second low-concentration diffusion layer region side, of a second impurity having a same polarity as the first impurity in a higher concentration than the first impurity with which the first low-concentration diffusion layer region is doped;
forming a second high-concentration diffusion layer region with doping, on a portion of the second low-concentration diffusion layer region located on a first low-concentration diffusion layer region side, of the second impurity in a higher concentration than the first impurity with which the second low-concentration diffusion layer region is doped;
oxidizing a surface of the substrate to form a first oxide film after the formation of the first high-concentration diffusion layer region and the second high-concentration diffusion layer region;
removing a first portion of the first oxide film with a mask disposed on the first oxide film and causing (i) a second portion of the first oxide film located in a region under the mask and (ii) a third portion of the first oxide film located in a region adjacent to the region under the mask, to remain;
forming a gate electrode on the second portion of the first oxide film; and
forming a silicide layer in a region on the substrate exposed by the removal of the first portion of the first oxide film.

16. The semiconductor device according to claim 1, wherein the substrate includes silicon.

17. The semiconductor device according to claim 1, wherein the semiconductor device includes a NAND flash memory.

18. The semiconductor device according to claim 1, wherein the semiconductor device includes an array chip.

19. The semiconductor device according to claim 1, wherein the second gate insulating film includes silicon oxide.
